(19) United States
(12) Patent Application Publication
(10) Pub. No.: US 2026/0333801 A1
(43) Pub. Date: Oct. 22, 2026

(54) TRENCH MOSFET WITH EPITAXIAL CHANNEL REGION

(71) Applicant: Microchip Technology Incorporated, Chandler, AZ (US)

(72) Inventors: Yogesh Kumar Sharma, Colorado Springs, CO (US); Shesh Mani Pandey, Gilbert, AZ (US)

(73) Assignee: Microchip Technology Incorporated, Chandler, AZ (US)

(21) Appl. No.: 19/652,264

(22) Filed: Apr. 20, 2026

Related U.S. Application Data
(60) Provisional application No. 63/791,915, filed on Apr. 21, 2025.

(51) Int. Cl. H10D 62/13; H10D 30/01; H10D 30/66; H10D 62/832

(52) U.S. Cl. CPC H10D 62/153; H10D 30/0297; H10D 30/668; H10D 62/8325

(57) ABSTRACT

A trench metal oxide semiconductor field-effect transistor includes an epitaxially grown rather than implanted doped channel region. A method of making same is also disclosed. A second volume of doped semiconductor material is epitaxially grown above a first volume of semiconductor material, with the first and second volumes of semiconductor material having opposite polarities. A source material is implanted into an upper region of the second volume of semiconductor material, leaving a lower region of the second volume of semiconductor material for a well. A trench is etched adjacent to the source material for a gate, and a channel extends through the well and alongside the trench. Epitaxially growing rather than implanting the second volume of semiconductor material results in a less Gaussian, or less normal, distribution of dopants and a more uniform distribution of dopants across the well through which the channel extends.

### RELATED APPLICATION

The present U.S. non-provisional patent application is related to and claims priority benefit of an earlier-filed U.S. provisional patent application titled “Trench MOSFET with Channel Epi,” Ser. No. 63/791,915, filed Apr. 21, 2025. The entire content of the identified earlier-filed application is incorporated by reference as if fully set forth herein.

### FIELD

The present disclosure relates to metal oxide semiconductor field-effect transistors and methods of making them, and more particularly, the various examples described herein concern a trench metal oxide semiconductor field-effect transistor with an epitaxially grown rather than implanted doped channel region, and a method of making a trench metal oxide semiconductor field-effect transistor with an epitaxially grown rather than implanted doped channel region.

### BACKGROUND

A metal-oxide-semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a trench MOSFET with an epitaxially grown rather than implanted doped well channel region, and a method of making a trench MOSFET with an epitaxially grown rather than implanted doped well channel region. Broadly, the doped well channel region is epitaxially grown above a drift layer, which results in a more uniform distribution of dopants, with substantially similar or equal concentrations throughout the channel region. Embodiments advantageously reduce the variability of electrical parameters and improve the performance of the device.

In an example, a field-effect transistor (FET) may include a source, a drain, a channel, and a well. The drain may be spaced apart from the source, and the channel may be located between the source and the drain. The well may be located beneath the source and include a top and a bottom. The channel may extend from the top to the bottom of the well. The well may be formed of a first volume of doped semiconductor material with a non-Gaussian distribution of dopants.

The preceding example may further include any one or more of the following features.

The channel may extend through the well and the first volume of doped semiconductor material.

The non-Gaussian distribution of dopants may be an approximately uniform distribution of dopants.

The uniform distribution of dopants may have a maximum dopant concentration variance from the top to the bottom of the well of approximately five (5) percent or less.

The uniform distribution of dopants may have a maximum dopant concentration variance from the top to the bottom of the well of approximately one (1) percent or less.

The FET may comprise a second volume of doped semiconductor material. The first volume of doped semiconductor material may have a first dopant polarity, and the second volume of doped semiconductor material may have a second dopant polarity opposite the first dopant polarity. The first volume of doped semiconductor material may be an epitaxial layer grown on the second volume of doped semiconductor (rather than implanted) in order to achieve the non-Gaussian distribution of dopants.

The source may comprise an implant within the first volume of doped semiconductor material.

The source may have the second dopant polarity.

The second volume of doped semiconductor material may present a top margin and a vertically opposite bottom margin. The top margin of the second volume of doped semiconductor material may contact the bottom of the well. The drain may be positioned at the bottom margin of the second volume of doped semiconductor material.

The FET may comprise a trench located adjacent to the source and well.

The FET may comprise a gate oxide lining the trench and being in contact with the source and the well, and a gate located within the trench inside of the gate oxide.

The first and second volumes of semiconductor material comprise silicon carbide.

The first volume of semiconductor material may be between one-half (0.5) and two and one-half (2.5) micrometers in vertical thickness.

The second volume of semiconductor material may be between eight (8) and twelve (12) micrometers in vertical thickness.

The trench may present laterally opposite first and second trench sides. The source, well, and channel may be adjacent the first trench side and constituting a first transistor side. The FET may comprise a second source, a second channel located between the second source and the drain, and a second well located beneath the second source and including a top and a bottom, and through which the second channel extends from the top to the bottom. The second well may be formed of the first volume of doped semiconductor material with the non-Gaussian distribution of dopants, such that the field-effect transistor is a dual channel device.

In another example, a method of making a FET may include the following operations. A first volume of semiconductor material having a first dopant polarity may be provided. A second volume of semiconductor material may be epitaxially grown above the first volume of semiconductor material, wherein the second volume of semiconductor material may have a second dopant polarity opposite the first dopant polarity and may include a non-Gaussian distribution of dopants. A source material may be implanted into an upper region of the second volume of semiconductor material, leaving a lower region of the second volume of semiconductor material for a well, wherein the well may include a top and a bottom. A trench may be etched adjacent to the source material for a gate, such that a channel may extend from the top to the bottom of the well and alongside the trench

The preceding examples may further include any one or more of the following features.

The operation of providing the first volume of semiconductor material including epitaxially growing the first volume of semiconductor material.

The method may include lining the trench with a gate oxide, and depositing a polysilicon material within the trench inside of the gate oxide.

The operation of epitaxially growing the second volume of semiconductor material may be performed such that the non-Gaussian distribution of dopants is uniform and has a maximum dopant concentration variance from the top to the bottom of the well of approximately five (5) percent or less.

The operation of epitaxially growing the second volume of semiconductor material may be performed such that the non-Gaussian distribution of dopants is uniform and has a maximum dopant concentration variance from the top to the bottom of the well of approximately one (1) percent or less.

The operation of providing the first volume of semiconductor material may be performed such that the first volume of semiconductor material may be between eight (8) and twelve (12) micrometers in vertical thickness.

The operation of epitaxially growing the second volume of semiconductor material may be performed such that the second volume of semiconductor material may be between one-half (0.5) and two and one-half (2.5) micrometers in vertical thickness.

This summary is not intended to identify essential features of the examples, and is not intended to be used to limit the scope of the claims. These and other aspects of the present examples are described below in greater detail.

### BRIEF DESCRIPTION OF THE DRAWINGS

Examples are described in detail below with reference to the attached drawing figures, wherein:

FIG. 1 is a graph of example doping concentrations versus distances from a surface of a volume of semiconductor material for an example source and a first example well formed using a conventional implantation process and for a second example well formed using an epitaxial growth process;

FIG. 2 is a cross-sectional elevation view of an example trench MOSFET with an epitaxially grown rather than implanted doped channel region

FIG. 3 is a flowchart of operations in an example of a method of making a trench MOSFET with an epitaxially grown rather than implanted doped channel region, such as the example trench MOSFET of FIG. 2;

FIG. 4A is a cross-sectional elevation view of example results of one or more operations in the method of FIG. 3, including the provision of a substrate, the epitaxial growth of a volume of semiconductor material for a drift region, and the epitaxial growth of a volume of semiconductor material for a well on the volume of semiconductor material;

FIG. 4B is a cross-sectional elevation view of example results of one or more operations in the method of FIG. 3, including the implantation of a material for a body and a material for a source, and the etching of a trench;

FIG. 4C is a cross-sectional elevation view of example results of one or more operations in the method of FIG. 3, including the provision of a gate oxide and the deposition of a polysilicon material for a gate in the trench; and

FIG. 4D is a cross-sectional elevation view of example results of one or more operations in the method of FIG. 3, including the provision of electrical terminals.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, top, below, bottom, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

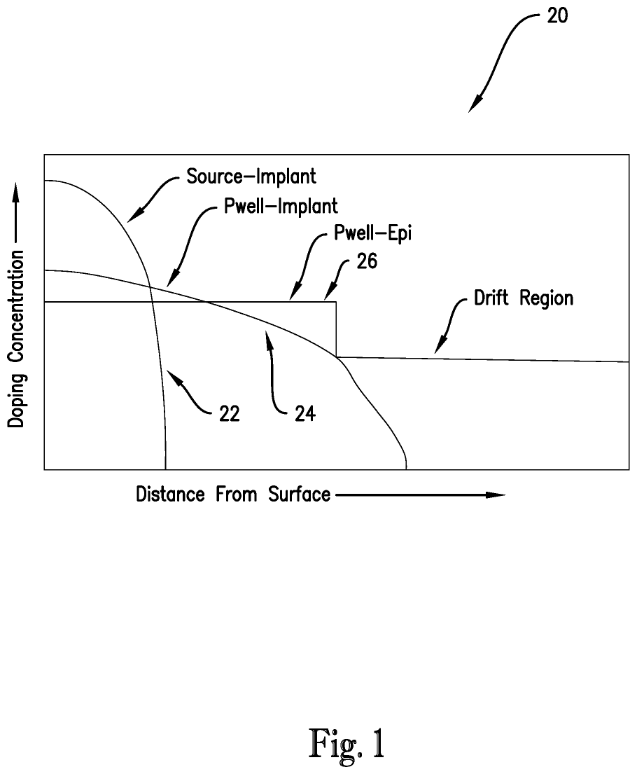

Traditional doping processes result in a Gaussian, or normal or non-uniform, distribution of dopants in at least a portion of the channel region associated with a well, which can increase the variability of electrical parameters and negatively affect the performance of the device. Referring to FIG. 1, a graph 20 shows example doping concentration (or dopant distribution) versus distance from a surface of a volume of semiconductor material for a source (“Source-Implant”) 22 and a Pwell (“Pwell-Implant”) 24 using a conventional implantation process that results in a non-uniform distribution of dopants, with higher concentrations closer to the surface and lower concentrations farther from the surface.

Examples provide a trench MOSFET with an epitaxially grown rather than implanted doped well channel region, and a method of making a trench MOSFET with an epitaxially grown rather than implanted doped well channel region. Broadly, the doped well channel region is grown over a drift layer. Referring again to FIG. 1, the graph 20 also shows an example doping concentration versus distance from a surface for a Pwell (“Pwell-Epi”) 26 using an epitaxial growth process that results in a more uniform distribution of dopants, with substantially similar or approximately equal or equal concentrations closer to the surface and farther from the surface. The threshold voltage (Vt) remains substantially the same even if the depth of the source implant is changed. Examples avoid using high implant energies that can cause damage and a rougher interface (especially for silicon carbide (SiC)) devices with the gate oxide at the trench sidewall surface. Thus, examples advantageously provide a more uniform dopant distribution in the well channel region and thereby reduce the variability of electrical parameters and improve the performance of the device.

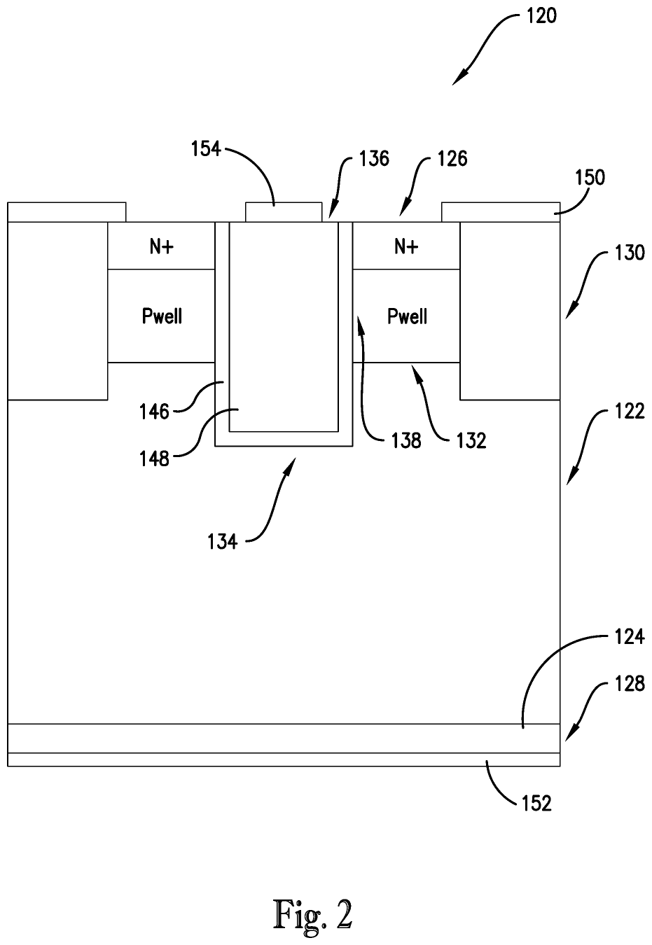

Referring to FIG. 2, an example trench MOSFET 120 with an epitaxially grown rather than implanted doped channel region is shown including a first volume of semiconductor material 122, a doped substrate material 124, a source 126, a drain 128, a body 130, a well 132, a trench 134, and a gate 136. The natures and locations of the MOSFET structures and materials may be different from the examples that are described and shown and may be substantially conventional or unconventional in their formation and operation.

The first volume of semiconductor material 122 may include a first end, a second end, a left side, and a right side. The first volume of semiconductor material 122 may be constructed from or otherwise include an N-type epitaxial semiconductor material such as silicon carbide (SiC), although certain examples contemplate the semiconductor material being alternatively formed of silicon (Si) or gallium nitride (GaN). The first volume of semiconductor material 122 may be approximately between eight (8) and twelve (12) micrometers in thickness, or approximately ten (10) micrometers in thickness. The doped substrate material 124 may be located at one end or side (e.g., the second end, as shown) of the volume of semiconductor material 122, and may be constructed from or otherwise include an N+ substrate material.

The source 126 may be located at the first end of the first volume of semiconductor material 122 adjacent to the trench 134, may provide an entrance for charge carriers, and may be constructed from or otherwise include an N+ material. The drain may be spaced apart from the source 126 (e.g., at the second end, as shown), may provide an exit for the charge carriers, and may be provided by the doped substrate material 124. A channel 138 through which the charge carriers move may extend through the well 132 in a region between the source 126 and the drain 128. The body 130 may be located adjacent to the source 126 at the first end of the volume of semiconductor material 122, may cooperate with the gate 136 to control the movement of charge carriers through the channel 138 between the source 126 and the drain 128, and may be constructed from or otherwise include a P+ material. The well 132 may be located at least partially below the source 126, may facilitate formation of the channel 138, and may include a semiconductor material that is oppositely doped relative to the first volume of semiconductor material 122. In this example, the semiconductor material of the well 132 may include a P-type epitaxial semiconductor material semiconductor such as silicon carbide (SiC), although certain examples contemplate the semiconductor material being alternatively formed of silicon (Si) or gallium nitride (GaN). The semiconductor material of the well 132 may be epitaxially grown on the volume of semiconductor material 122 rather than implanted into the volume of semiconductor material 122, resulting in a more uniform distribution of dopants in the channel region of the well 132. For example, the concentration of dopants may vary from the top of the well 132 to the bottom of the well 132, i.e., along the length of the channel 138 through the well 132, by approximately five percent (5%) or less, or by approximately one percent (1%) or less. The degree to which the concentration of dopants may vary in the vertical direction may be referred to as the “maximum dopant contraction variance.”

As will be further described herein, the semiconductor material forming the well 132 may be grown epitaxially on and above the first volume of semiconductor material 122 and may be generally referred to as a second volume of semiconductor material. It may said that the first volume of semiconductor material 122 presents a bottom margin in contact with the substrate 124 and top margin in contact with the well 132 (or second volume of P-doped semiconductor material). The second volume of semiconductor material extends from the top margin of the first volume of semiconductor material 122 to the top of the MOSFET 120. The source 126 and body 130 are formed (e.g., implanted) within the second volume of P-type material. Further, the body 130 and the trench 134 may extend through the second volume of P-doped semiconductor material and past the top margin of the first volume of semiconductor material 122, such that a portion of the body 130 and trench 134 are located within the first volume of N-doped semiconductor material.

In this particular example of a FET, the source 126, body 130, and Pwell 132 each include left and right instances located on opposite sides of the centrally located trench 134, as shown. The source 126 and body 130 may be constructed by implanting (using, e.g., an ion implanter) or otherwise introducing suitable dopants into areas of the volume semiconductor material 122 and/or into areas of the volume of the P-doped semiconductor material that has been epitaxially grown on the volume of semiconductor material 122. These components and materials and their sizes and positions may vary depending on the nature of and application for the device.

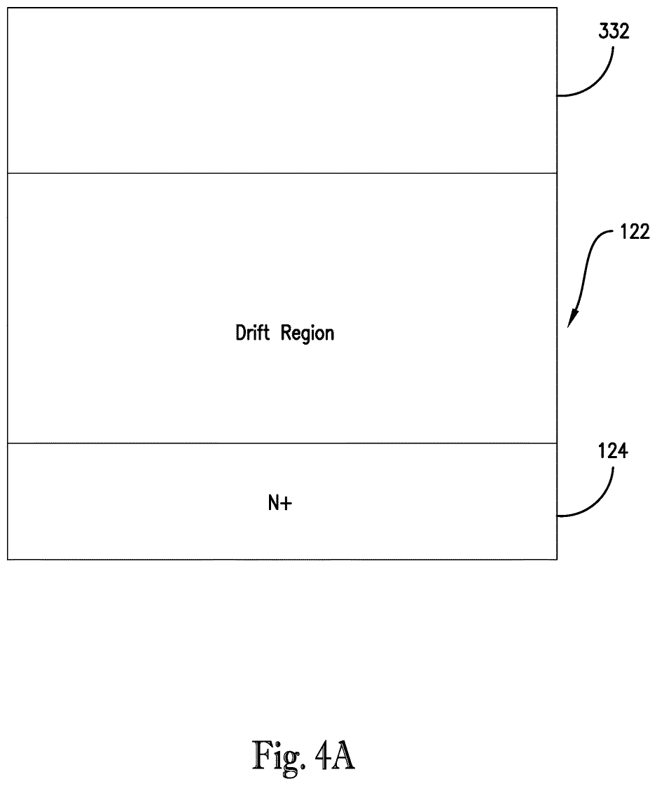

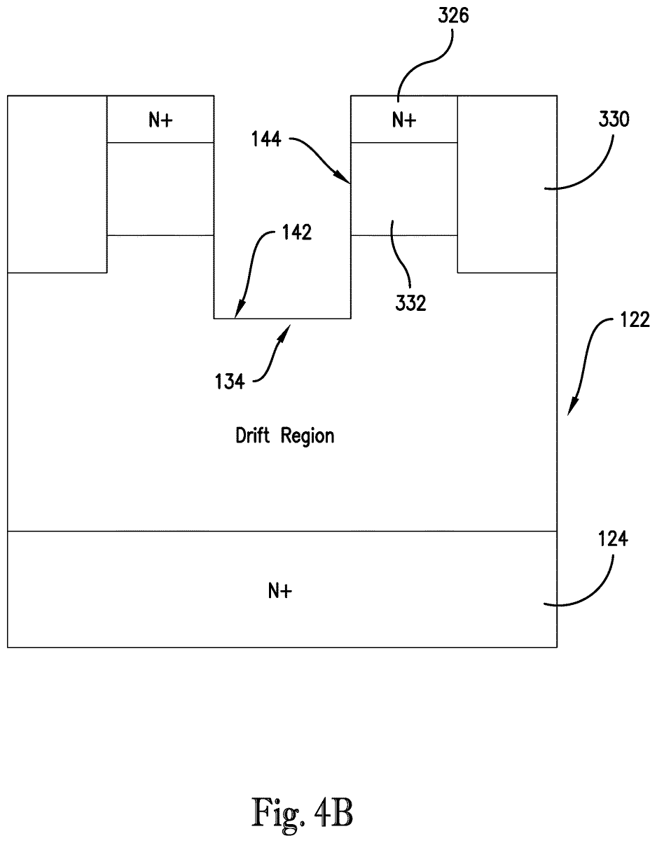

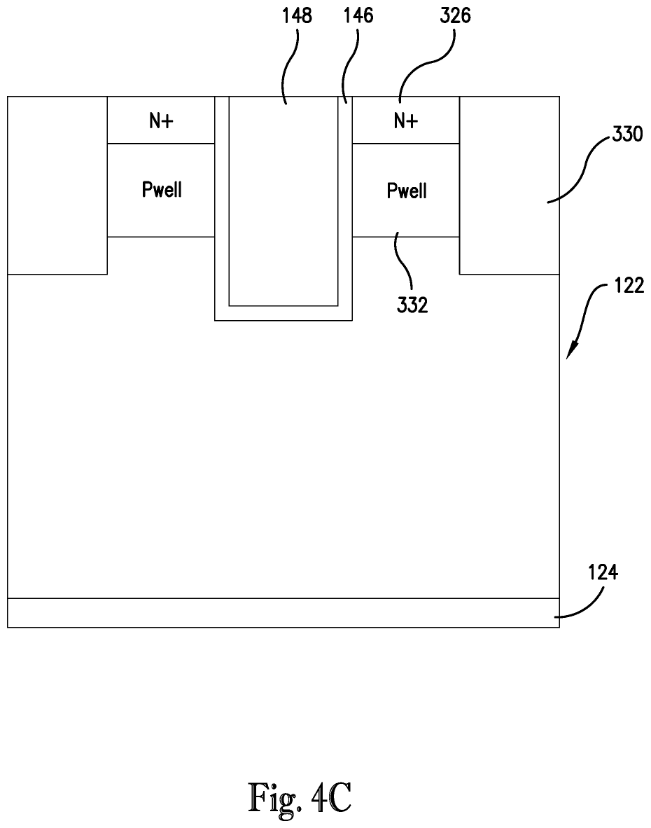

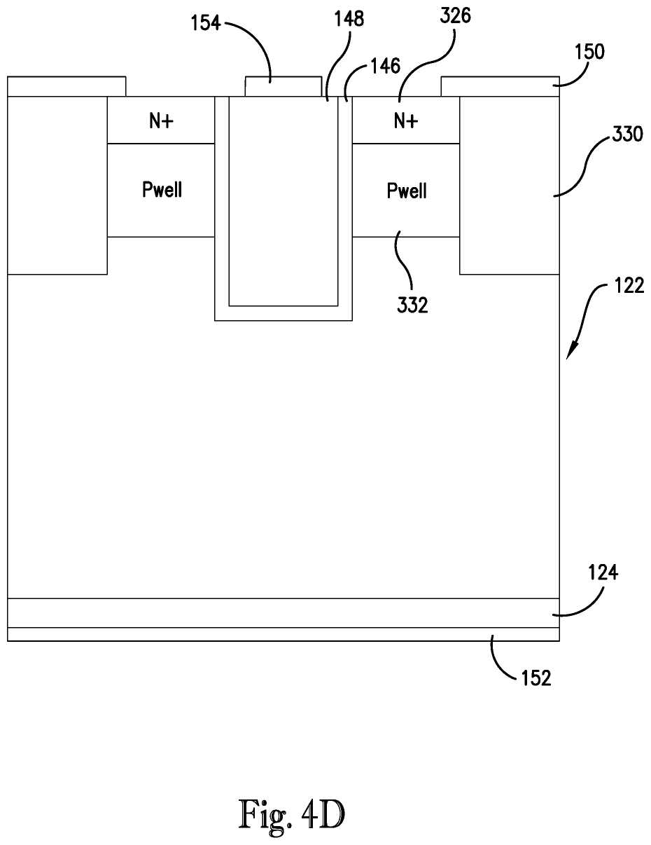

The trench 134 may be a cavity etched or otherwise created in the first end of the volume of semiconductor material 122 so as to extend alongside the source 126 and Pwell 132, or between the left and right instances of the source 126, body 130, and Pwell 132. The trench 134 may include a generally horizontal bottom 142 and a generally vertical sidewall 144 (seen in FIG. 4B). It will be appreciated that the trench 134 is a three-dimensional structure and so may have left, right, front, and back sidewalls, and the term “sidewall,” as used herein may refer to one, some, or all of these vertical surfaces.

The gate 130 may include a gate oxide 146, or dielectric material, (e.g., SiO2) on the bottom 142 and sidewall 144 of the trench 134, and a doped polysilicon material 148 deposited or otherwise provided in the oxide-lined trench 134. The gate 136 may cooperate with the body 130 to control the movement of charge carriers through the channel 38. Electrical terminals 150, 152, 154 may be added to, respectively, the source 126 and body 130, the drain 128, and the gate 136 to facilitate applying appropriate electrical voltages for operation of the MOSFET 120. Additional components may be incorporated as desired.

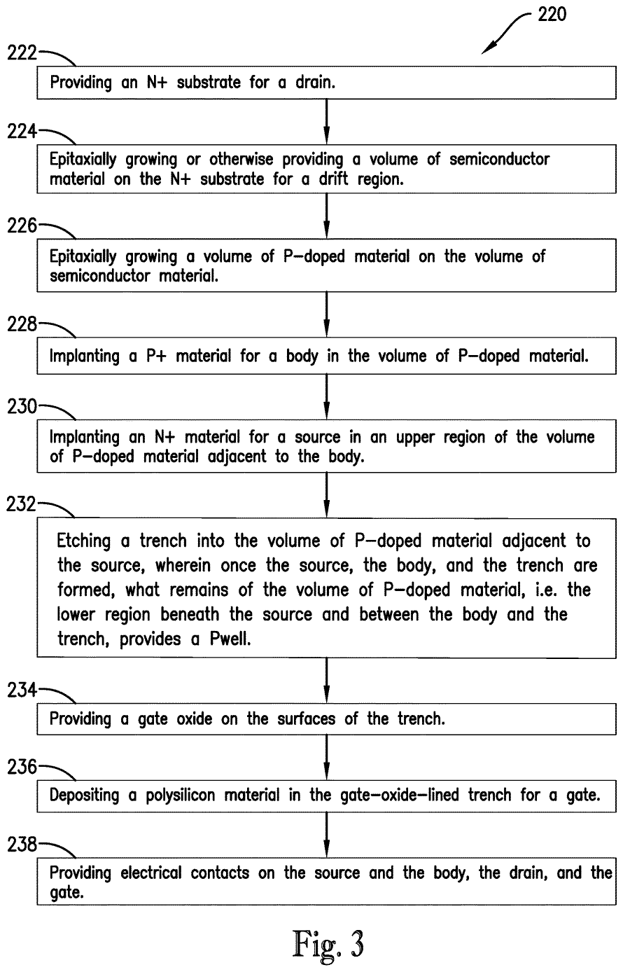

Referring to FIG. 3, an example of a method 220 of making a trench MOSFET, such as the trench MOSFET 120 described above and shown in FIG. 2, with an epitaxially grown rather than implanted doped channel region, may include the operations set forth below. Referring additionally to FIGS. 4A-D, example results of at least some of the operations of the method 220 are shown.

A substrate 124 may be provided for a drain 128, as shown in 222 and seen in FIG. 4A. In the illustrated example, the substrate comprises an N+ material.

A first volume of semiconductor material 122 may be epitaxially grown or otherwise provided for a drift region on the substrate 124, as shown in 224 and seen in FIG. 4A. The first volume of semiconductor material 122 may have the same polarity as the substrate and, in the illustrated example, may be constructed from or otherwise include an N-type epitaxial semiconductor material. In the illustrated example, the first volume of semiconductor material 122 is silicon carbide (SiC), although some examples permit the use of alternative semiconductor material(s), such as silicon (Si) and/or gallium nitride (GaN). The first volume of semiconductor material 122 may be approximately between eight (8) and twelve (12) micrometers in thickness (measured in the vertical direction depicted in FIG. 4A), or approximately ten (10) micrometers in thickness.

A second volume of semiconductor material 332 may be epitaxially grown on the first volume of semiconductor material 122, as shown in 226 and seen in FIG. 4A. The second volume of semiconductor material 332 may have an opposite dopant polarity than the first volume of semiconductor material 122 and, in the illustrated example, may be constructed from or otherwise include a P-type epitaxial semiconductor material. In the illustrated example, the second volume of semiconductor material 332 is silicon carbide (SiC), although some examples permit the use of alternative semiconductor material(s), such as silicon (Si) and/or gallium nitride (GaN). The second volume of semiconductor material 332 may be approximately between one-half (0.5) and two and one-half (2.5) micrometers in thickness, or approximately between one (1) and two (2) micrometers in thickness. As discussed, growing the second volume of P-doped semiconductor material 332 results in a more uniform distribution of P-dopants compared to the conventional technique of implanting P-dopants into a volume of semiconductor material. For example, the uniformity of the P-doped semiconductor material 332 is such that the maximum dopant concentration variation (the maximum amount the concentration of dopants may vary) from the top of the Pwell 132 to the bottom of the Pwell 132, i.e., along the length of the channel 138 through the Pwell 132, is approximately five percent (5%) or less, or is approximately one percent (1%) or less.

According to some examples, the substrate 124 and first and second volumes of semiconductor material 122, 332 may be provided as a single (assembled or unitary) structure before the following processing steps are performed. For example, the substrate 124 and first and second volumes of semiconductor material 122, 332 may be provided to (or received or acquired by) as a preassembled wafer to the party who then performs the following transistor processing steps to the wafer. Such a relationship may exist between a transistor fabricator and a wafer vendor/supplier.

A P+ material 330 may be implanted for a body 130 in the second volume of P-doped semiconductor material 332 (and, as desired, extending into the first volume of N-type semiconductor material 122 beneath the second volume of P-doped semiconductor material 332), as shown in 228 and seen in FIG. 4B. An N+ material 326 may be implanted (or otherwise provided) for a source 126 into an upper region of the volume of P-doped semiconductor material 332 adjacent to the body 130, as shown in 230 and seen in FIG. 4B. It is particularly noted that the source implant is dimensioned and configured not to extend all the way down through (to the lowermost margin) of the second volume of P-doped semiconductor material 332, such that a portion of the epitaxial material remains below the source 126.

A trench 134, including a generally horizontal bottom 142 and a generally vertical sidewall 144, may be etched into the second volume of P-doped semiconductor material 332 (and, as desired, extending into the first volume of N-type semiconductor material 122 beneath the second volume of P-doped semiconductor material 332) adjacent to the source, as shown in 232 and seen in FIG. 4B. In this particular example of a FET, the source 126, body 130, and Pwell 132 may each include left and right instances located on opposite sides of the centrally located trench 134, as shown. In particular, the trench 134 may be etched through the N+ source material 326 and through the volume of P-doped semiconductor material 332 to leave left and right subvolumes of each material and corresponding left and right instances of the source 126 and Pwell 132. The left and right instances of the FET components thereby create dual channels, with each channel being defined along a respective side of the trench 134. Such a FET construction may be referred to as a “dual channel MOSFET.” However, it will be appreciated that, according to certain examples, the FET may alternatively include only single instances of the source, Pwell, and body along just one side of the trench, thereby providing a so-called “single channel MOSFET.” As seen in FIG. 4B, once the source 126, the body 130, and the trench 134 are formed, what remains of the second volume of P-doped semiconductor material 332, i.e. the lower region beneath the source 126 and between the body 130 and the trench 134, may provide a Pwell 132. A gate oxide (e.g., SiO2) 146 may be grown, deposited, or otherwise provided on the bottom 142 and sidewall(s) 144 of the trench 134, as shown in 234 and seen in FIG. 4C. A polysilicon material 148 may be deposited for a gate 136 in the gate-oxide-lined trench 134, as shown in 236 and seen in FIG. 4C. Electrical contacts 150, 152, 154 may be provided on, respectively, the source 126 and the body 130, the drain 128, and the gate 136, to facilitate the application of various voltages, as shown in 238 and seen in FIG. 4D.

Additional processing may be performed as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon, gallium nitride, zinc oxide, or other suitable material.

Additionally, in general, unless otherwise specified or unless one with ordinary skill in the art would understand otherwise, doping characterized as “++” (e.g., P++) will have a relatively higher concentration of dopants than “+” (e.g., P+) doping, “+” doping will have a relatively higher concentration than “-well” (e.g., P-well) doping, and “-well” doping will have a relatively higher concentration of doping than “−” (e.g., P−) doping. In general, doping concentrations (typically measured in parts-per-cubic-centimeter) for contact implants (e.g., sources, drains, body contacts) may be approximately between 5×10\hat{ }18 and 1×10\hat{ }22; doping concentrations for channel and threshold forming implants (e.g., P-wells) may be approximately between 5×10\hat{ }15 and 5×10\hat{ }17; doping concentrations for shielding implants may be approximately between 5×10\hat{ }17 and 5×10\hat{ }19; doping concentrations for conductivity improvement implants (e.g., N-doping in the junction field-effect transistor neck region of a metal oxide semiconductor field-effect transistor) may be approximately between 1×10\hat{ }17 and 1×10\hat{ }19; and doping concentrations for drift regions (e.g., N doping) may be approximately between 1×10\hat{ }15 and 1×10\hat{ }16. In some examples, the doping concentration range for the drift region may be widened, for example to approximately between 1×10\hat{ }14 and 1×10\hat{ }18.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right and/or left side of a volume of semiconductor material may be to the conceptual limit of a particular unit cell and not to an actual physical end of the material. While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A field-effect transistor comprising:
a source;
a drain spaced apart from the source;
a channel located between the source and the drain; and
a well located beneath the source and including a top and a bottom, and through which the channel extends from the top to the bottom,
the well being formed of a first volume of doped semiconductor material with a non-Gaussian distribution of dopants.

2. The field-effect transistor of claim 1,
the channel extending through the well and the first volume of doped semiconductor material.

3. The field-effect transistor of claim 1,
the non-Gaussian distribution of dopants being a uniform distribution of dopants.

4. The field-effect transistor of claim 3,
the uniform distribution of dopants having a maximum dopant concentration variance from the top to the bottom of the well of five (5) percent or less.

5. The field-effect transistor of claim 4,
the uniform distribution of dopants having a maximum dopant concentration variance from the top to the bottom of the well of one (1) percent or less.

6. The field-effect transistor of claim 1,
the first volume of doped semiconductor material having a first dopant polarity; and
a second volume of doped semiconductor material having a second dopant polarity opposite the first dopant polarity,
the first volume of doped semiconductor material being an epitaxial layer grown on the second volume of doped semiconductor material.

7. The field-effect transistor of claim 6,
the source comprising an implant within the first volume of doped semiconductor material,
the source having the second dopant polarity.

8. The field-effect transistor of claim 7,
the second volume of doped semiconductor material presenting a top margin and a vertically opposite bottom margin,
the top margin of the second volume of doped semiconductor material contacting the bottom of the well,
the drain being positioned at the bottom margin of the second volume of doped semiconductor material.

9. The field-effect transistor of claim 1, comprising:
a trench located adjacent to the source and well.

10. The field-effect transistor of claim 9, comprising:
a gate oxide lining the trench and being in contact with the source and the well; and
a gate located within the trench inside of the gate oxide.

11. The field-effect transistor of claim 10,
the first volume of doped semiconductor material having a first dopant polarity; and
a second volume of doped semiconductor material having a second dopant polarity opposite the first dopant polarity,
the first volume of doped semiconductor material being an epitaxial layer grown on the second volume of doped semiconductor material,
the first and second volumes of semiconductor material comprising silicon carbide.

12. The field-effect transistor of claim 11,
the first volume of semiconductor material being between one-half (0.5) and two and one-half (2.5) micrometers in vertical thickness,
the second volume of semiconductor material being between eight (8) and twelve (12) micrometers in vertical thickness.

13. The field-effect transistor of claim 10,
the trench presenting laterally opposite first and second trench sides,
the source, well, and channel being adjacent the first trench side and constituting a first transistor side;
a second source;
a second channel located between the second source and the drain; and
a second well located beneath the second source and including a top and a bottom, and through which the second channel extends from the top to the bottom,
the second well being formed of the first volume of doped semiconductor material with the non-Gaussian distribution of dopants, such that the field-effect transistor is a dual channel device.

14. A method of making a field-effect transistor, the method comprising:
providing a first volume of semiconductor material having a first dopant polarity;
epitaxially growing a second volume of semiconductor material above the first volume of semiconductor material, wherein the second volume of semiconductor material has a second dopant polarity opposite the first dopant polarity and includes a non-Gaussian distribution of dopants;
implanting a source material into an upper region of the second volume of semiconductor material, leaving a lower region of the second volume of semiconductor material below the source material for a well,
the well including a top and a bottom,
the source material having the first dopant polarity; and
etching a trench adjacent to the source material for a gate,
wherein a channel extends from the top to the bottom of the well and alongside the trench.

15. The method of claim 14,
the operation of providing the first volume of semiconductor material including epitaxially growing the first volume of semiconductor material.

16. The method of claim 14, comprising:
lining the trench with a gate oxide; and
depositing a polysilicon material within the trench inside of the gate oxide.

17. The method of claim 14,
the operation of epitaxially growing the second volume of semiconductor material being performed such that the non-Gaussian distribution of dopants is uniform and having a maximum dopant concentration variance from the top to the bottom of the well of five (5) percent or less.

18. The method of claim 17,
the operation of epitaxially growing the second volume of semiconductor material being performed such that the distribution of dopants has a maximum dopant concentration variance from the top to the bottom of the well of one (1) percent or less.

19. The method of claim 14,
the operation of providing the first volume of semiconductor material being performed such that the first volume of semiconductor material is between eight (8) and twelve (12) micrometers in vertical thickness.

20. The method of claim 19,
the operation of epitaxially growing the second volume of semiconductor material being performed such that the second volume of semiconductor material is between one-half (0.5) and two and one-half (2.5) micrometers in vertical thickness.
